(19) United States
(12) Patent Application Publication
(10) Pub. No.: US 2015/0318139 A1
(43) Pub. Date: Nov. 5, 2015

(54) TARGET DEVICE, LITHOGRAPHY APPARATUS, AND ARTICLE MANUFACTURING METHOD

(71) Applicant: CANON KABUSHIKI KAISHA, Tokyo (JP)

(72) Inventor: Mitsuaki Amemiya, Saitama-shi (JP)

(21) Appl. No.: 14/700,237

(22) Filed: Apr. 30, 2015

(30) Foreign Application Priority Data
May 2, 2014 (JP) 2014-095021

(51) Int. Cl. H01J 37/04; H01J 37/147; H01J 37/20

(52) U.S. Cl. CPC H01J 37/045; H01J 37/20; H01J 37/1474; H01J 2237/15; H01J 2237/063; H01J 2237/303; H01J 2237/043

(57) ABSTRACT

Provided is a target device for scattering a charged particle incident thereon, the device comprising: a base; a reference mark provided on the base and having a range of the charged particle therein smaller than a range of the charged particle in the base; and a shield provided on the base apart from the reference mark and having a range of the charged particle therein smaller than the range of the charged particle in the base.

### BACKGROUND OF THE INVENTION

1. Field of the Invention

The present invention relates to a target device, a lithography apparatus, and an article manufacturing method.

2. Description of the Related Art

Drawing apparatuses (Lithography apparatuses) that pattern a substrate with a charged particle beam such as an electron beam or the like are known. Such drawing apparatuses have a stage for holding the substrate, and the stage has a target device that includes a reference mark. In this case, for example, a position of the charged particle beam (where the charged particle beam is irradiated) may be calibrated by detecting reflected electrons that can be obtained on scanning the reference mark with the charged particle beam. The target device is constituted, for example, by forming a reference mark made of a heavy metal such as tungsten (W) on a base made of silicon (Si). In addition, the relative position between the charged particle beam and the reference mark may be determined based on a difference in a backscatter coefficient of bulk Si and W. Note that the backscatter coefficient is a coefficient represented, for example, by the number of the reflected electrons/ the number of incident electrons. For example, the backscatter coefficient of bulk Si and W with regard to the incident electrons with 10 keV or more of energy is 0.22 and 0.43 respectively. In this case, the ratio of signal intensity is 1.9, and the contrast is 0.31.

As disclosed above, when the reflected electrons are measured, it is better that the ratio of signal intensity (or the contrast) is high from the point of view of measurement accuracy. Accordingly, Japanese Patent Laid-Open No. H8-8176 discloses a calibration method for reducing reflected electrons from a substrate by forming a thinner W film on the surface of a Si substrate on which a reference mark is provided in advance, in order to increase the ratio of signal intensity. In addition, Japanese Patent Laid-Open No. 2005-310910 discloses a target device in which a material of a base is carbon. Note that a description is given of the range of electrons for each element with respect to the energy of incident electrons in T. Tabata, R. Ito and S. Okabe, “Generalized semiempirical equations for the extrapolated range of electrons”, Nucl. Instr. Meth., 15 Aug. 1972, Vol. 103, p. 85-91. This document will be referred below to consider an area where electrons incident to a substance escape from the surface thereof as reflected electrons.

However, the calibration method disclosed in Japanese Patent Laid-Open No. H8-8176 has a small effect due to increased ratio of signal intensity since the reflection coefficient from the base remains high even if a thinner W film is formed. Furthermore, it is difficult for the target device disclosed in Japanese Patent Laid-Open No. 2005-310910 to obtain an effective ratio of signal intensity with several ten keV of the energy of the incident electrons. Moreover, there is a possibility that an electron beam of about several—10% of the irradiating state are irradiated, even if the drawing apparatus switches the electron beam to non-irradiating (blanking) state. In this case, it is even more difficult to obtain the suitable ratio of signal intensity due to the increased background signal.

### SUMMARY OF THE INVENTION

The present invention provides, for example, a target device advantageous in terms of precision with which a characteristic of a charged particle beam is measured.

According to an aspect of the present invention, a target device for scattering a charged particle incident thereon is provided that comprises: a base; a reference mark provided on the base and having a range of the charged particle therein smaller than a range of the charged particle in the base; and a shield provided on the base apart from the reference mark and having a range of the charged particle therein smaller than the range of the charged particle in the base.

Further features of the present invention will become apparent from the following description of exemplary embodiments (with reference to the attached drawings).

### BRIEF DESCRIPTION OF THE DRAWINGS

FIG. 1 illustrates a configuration of a first target device according to a first embodiment of the present invention.

FIG. 2 illustrates an example of a locus of electrons incident to a base.

FIG. 3 a graph illustrating an unit range with respect to the energy of incident electrons for each element.

FIGS. 4A and 4B illustrate an escape area of reflected electrons from a surface of a member.

FIG. 5 is a graph illustrating the signal intensity with respect to a position in the first target device.

FIG. 6 illustrates a configuration of a drawing apparatus according to a second embodiment of the present invention.

FIG. 7 illustrates a configuration of a second target device according to the second embodiment of the present invention.

FIG. 8 illustrates a shape of an electron beam group irradiated on a wafer.

FIGS. 9A and 9B illustrate an irradiating state of the electron beams during positional calibration in the second embodiment.

FIG. 10 is a graph illustrating signal intensity with respect to a position in the second target device.

FIGS. 11A to 11C illustrate a profile of the electron beams corresponding to FIG. 10.

FIG. 12 illustrates the configuration of the target device for explaining a shape condition of a shield.

FIG. 13 illustrates a configuration of a target device according to a third embodiment of the present invention.

FIG. 14 illustrates an irradiating state of the electron beams during positional calibration in the third embodiment.

FIG. 15 illustrates a configuration of a target device according to a fourth embodiment of the present invention.

FIG. 16 illustrates an A-A′ section in FIG. 15.

### DESCRIPTION OF THE EMBODIMENTS

Hereinafter, preferred embodiments of the present invention will be described with reference to the drawings.

### First Embodiment

Firstly, a description will be given of a target device according to a first embodiment of the present invention. A drawing apparatus is used as a lithography apparatus, which forms a latent image pattern on a substrate (a resist thereon) by deflection scanning and blanking, for example, with a charged particle beam such as an electron beam. Such a drawing apparatus calibrates a position of the electron beam to be irradiated on a substrate stage for holding the substrate before drawing by using a target device. Hereinafter, this calibration is simply referred to as “positional calibration”. In this case, the drawing apparatus determines the necessity of calibration and the amount of calibration by irradiating and scanning with the electron beam on the target device arranged on the surface of the substrate stage and measuring (detecting) the reflected electrons that are emitted at this time. While the reflected electrons emitted from the target device are typically measured for the positional calibration and the present embodiment follows this, the present embodiment may be applied to a case where electrons emitted from the base are, for example, secondary electrons. In addition, a drawing apparatus using an electron beam is described below, but the drawing apparatus may use other charged particle beam such as an ion beam. Hereinafter, “scanning” may mean not only scanning with the electron beam with respect to the fixed reference mark but scanning the reference mark with respect to the fixed electron beam. In regards to this, in particular, “scanning direction” has both means, and is synonymous with a direction of the relative movement for relatively moving the electron beam and the reference mark. Furthermore, in the figures explained below, the Z-axis is aligned in a direction (vertical direction, plus direction is upward) along with the electron beam to be irradiated to the target device, the Y-axis is aligned in a plane perpendicular to the Z-axis, and the X-axis is aligned in a direction orthogonal to the Y-axis.

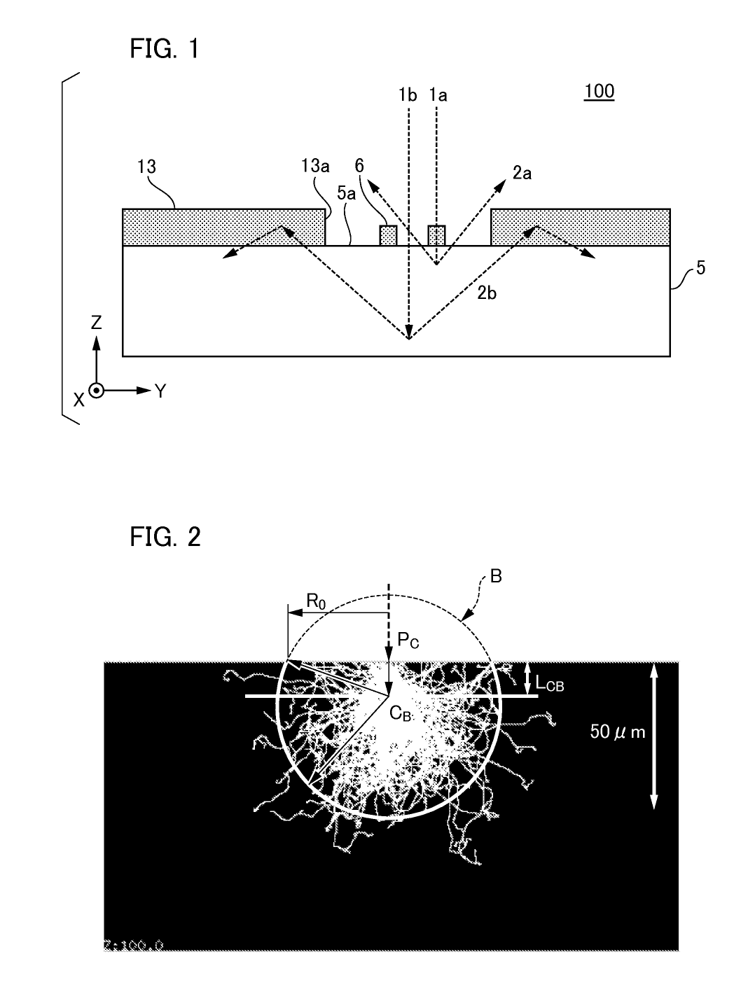

FIG. 1 is a schematic cross-sectional diagram illustrating a configuration of the first target device 100 according to the present embodiment. The target device 100 is applied when an electron beam is used for drawing, and includes a base 5, a reference mark 6, and a shield 13. The base 5 is a plate portion made of silicon (Si). The reference mark (target) 6 is a pattern portion that is made of a heavy metal of tungsten (W) and is arranged (configured) on the base 5. Note that FIG. 1 illustrates the reference mark 6 for measuring in the Y-axis direction that has a plane shape in which the plurality of lines are arranged parallel to the scanning direction, that is, two linear patterns extending in the X-axis direction are arranged in the Y-axis direction. In addition, there is a reference mark (not shown) for measuring in the X-axis direction, in which two linear patterns extending in the Y-axis direction are arranged in the X-axis direction. The shield 13 is arranged on the base 5 around a region where the reference mark 6 is arranged. In other words, the shield 13 is a shielding member having an aperture region 13a as the region where the reference mark 6 is arranged. The shield 13 may be configured of W as well as the material of the reference mark 6, but may be configured of a heavy metal that is different from that of the reference mark 6. In addition, the thickness of the shield 13 is the same as that of the reference mark 6, but it is desired that the shield 13 is thicker than the reference mark 6.

Next, a detailed description will be given of the target device 100. Firstly, as a basic principle for showing the configuration of the target device 100, a description will be given of a condition in which the electrons are incident to a member made of a material, and then the reflected electrons escape from the surface of the member. FIG. 2 is a cross-sectional diagram illustrating a locus of the electrons with energy of 100 keV incident to a member made of Si, obtained by a Monte Carlo calculation, as an example. After the electrons are incident to the member, it is considered that the electrons linearly enter to a depth, and scatter around a point C_{B} (scattering point) in every direction. In this case, the maximum entering depth of the electrons is about 50 μm and is about the same as the range Rₑ of the electrons (=54 μm). Here, the range is synonymous with a movement distance in the member. When the film serving as the member is thin, a transmittance of the entered electrons to the film becomes small in proportion to the film thickness. Thus, the range is strictly defined by a film thickness with a transmittance of zero when the proportion is liner-approximated. Note that there are electrons in actuality, which can move a longer distance than the range without losing energy in proportion to the movement distance, but such electrons are not considered since there are few of them and they have smaller energy than that of the surface, and thereby the influence given to measurement is small.

In order to escape the reflected electrons from the surface of the member, the reflected electrons requires to enter from a point, go and return within the member, and return to the surface again. Therefore, the maximum entering depth of the reflected electrons is a entering depth when the electrons that enter to a half of the range Rₑ return on the same path, and at this time, the electrons exist alone, which have no energy and return in the linear path. Accordingly, it is assumed that the depth L_{CB} of the point C_{B} in which the electrons can be considered to scatter in every direction is a half of the depth Rₑ/2 that the electrons having no energy in the surface of the member can arrive, that is, Rₑ/4. In addition, the movement area of the electrons scattered in the point C_{B} is represented by the circle “B” centered on the point C_{B} with a radius of ¾ of the range Rₑ. Based on the above, the escape area of the reflected electrons is an area contacting the circle “B” with the surface of the member, that is, an area with the radius R₀ centered on the entering point P_{c}, and the radius R₀ is represented by Equation 1.

$$\begin{matrix}[ Equation 1 ] & \\ {R}_{0} = \sqrt{{( 3 {R}_{e} / 4 )}^{2} - {( {R}_{e} / 4 )}^{2}} = \frac{\sqrt{2}}{2} {R}_{e} & ( 1 )\end{matrix}$$

In this way, the area (the circle region with the radius R₀) where the electrons incident to the member can escape from the surface as the reflected electrons are represented by using the range Rₑ as shown in Equation 1. The larger the value of the range Rₑ is, the larger the escape area is.

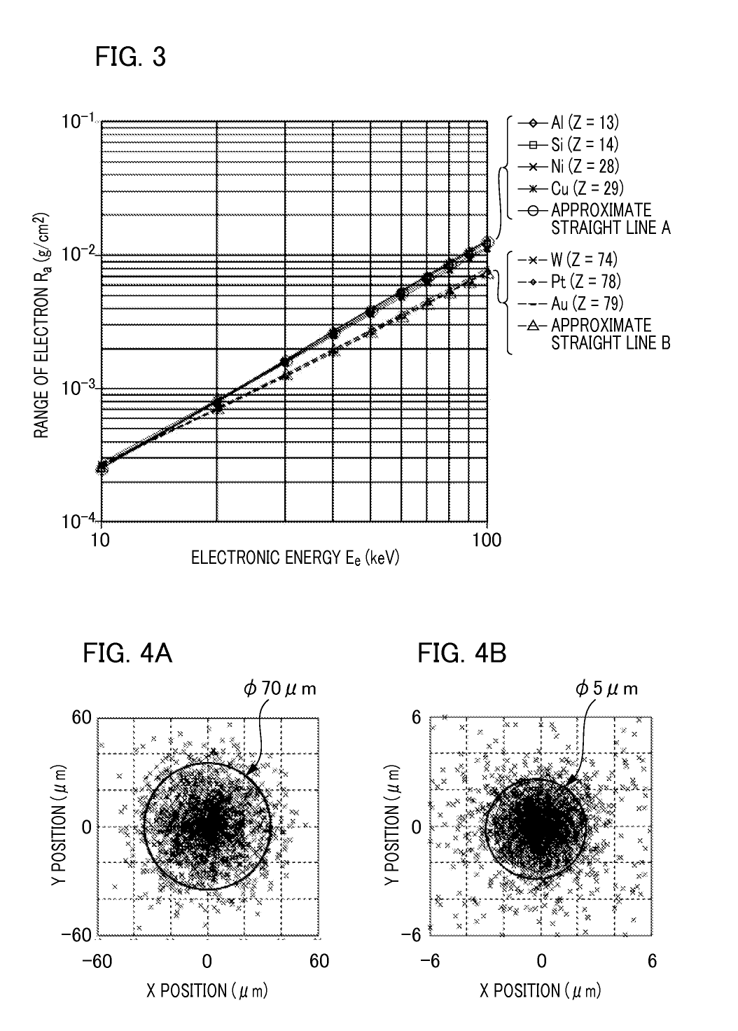

In contrast, the range Rₑ of the electrons depends on a kind and a density of a material constituting the member and the energy of the incident electrons. FIG. 3 is a graph illustrating the range Rₐ (unit range) of the electrons which is the product of the range Rₑ and the density with respect to the energy Eₑ of the incident electrons for the various elements, which is calculated in accordance with approximation shown in T. Tabata, R. Ito and S. Okabe, “Generalized semiempirical equations for the extrapolated range of electrons”, Nucl. Instr. Meth., 15 Aug. 1972, Vol. 103, p. 85-91. Here, if the density is denoted as ρ, then the range Rₑ of the electrons is represented by Rₑ=Rₐ/ρ. The unit range Rₐ is varied by the energy Eₑ of the incident electrons and an atomic number Z of the material of the member. Furthermore, the unit range Rₐ can be divided to that of materials such as aluminum (Al) or Si which can be employed as the material of the base and have the atomic number Z of 30 or less, and that of materials such as W, platinum (Pt), or gold (Au), which can be employed as the material of the reference mark 6 and have the atomic number Z of 73 or more.

The range Rₑ of the electrons having characteristics shown in FIG. 3 is represented by the approximation applicable to all the elements. Here, when the approximation is performed only for the base 5 and the reference mark 6, and the values plotted in FIG. 3 are used, the range R_{eB} in the base 5 and the range R_{eT} in the reference mark 6 are represented by Equation 2, corresponding to the approximate straight line “A”, and Equation 3, corresponding to the approximate straight line “B” respectively.

[Equation 2]

R_{eR}=5×10⁻⁶×Eₑ^{1.7}/ρ_{B} (2)

[Equation 3]

R_{eT}=10⁻⁵Eₑ¹⁴⁴/ρ_{T} (3)

In these equations, “ρ_{B}” is the density of the material constituting the base 5, “ρ_{T}” is the density of the material constituting the reference mark 6, and their units are “g/cm³”. In addition, the unit of each range R_{eB} and R_{eT} is “cm”, and the unit of the energy of the incident electrons is “keV”. For example, if the electrons have an energy of 100 keV, the range R_{eB} within Si (Density: 2.34 g/cm³) is determined to be 54 μm by Equation 2. In contrast, if the electrons have an energy of 100 keV, the range R_{eT} within W (Density: 19.3 g/cm³) is determined to be 3.9 μm by Equation 3. Thus, the escape areas of the reflected electrons on the surfaces of the materials of Si and W for the electrons of 100 keV are determined by Equation 1 to be circular regions with diameters of 76 μm and 5.5 μm respectively.

FIGS. 4A and 4B illustrate escape areas of reflected electrons from the surfaces of materials to which the electrons have entered, obtained by the Monte Carlo calculation. Among them, FIG. 4A illustrates the case where the material is Si and FIG. 4B is illustrates the case where the material is W. Referring to FIGS. 4A and 4B, the values of the escape areas from the member, obtained by Equation 1, may be considered to be appropriate. In this way, the kind of the material of the member into which the electrons enter varies the escape area of the reflected electrons on the surface of the member.

Therefore, in the present embodiment, a difference in escape areas due to the material of the member into which the electrons enter is used, and the ratio of the signal intensity that can occur in the target device 100 is set to be high. The difference in the escape areas may be determined by the range Rₑ of electrons as shown in Equation 1, and when the density is the same, the range Rₑ of electrons may be determined by the type of atomic number Z as shown in FIG. 3. In addition, the reference mark 6 consists of a material having a small escape area, the base 5 consists of a material having a large escape area, and the shield 13 shields the region apart from an incident point as shown below.

Returning to FIG. 1, in an aperture region 13a, excluding a region where the reference mark 6 is arranged, the surface (exposed surface 5a) of the base 5 is exposed in a direction to which the electron beam (electrons) 1 is incident. An area from which the electrons 1a incident to the reference mark 6 escape by backscatter thereof as the reflected electrons 2a is an area with a radius of about 3 μm (0.7 Rₑ) from the incident point. In contrast, an area from which the electrons 1b directly incident to the exposed surface 5a escape by backscatter thereof as the reflected electrons 2b is judged as an area with a radius of about 38 μm from the incident point, and the shield 13 shields the outside of this area on the surface of the base 5. Even if the electrons 1b directly incident to the exposed surface 5a scatter within the base 5 and arrive at the shield 13 as the reflected electrons 2b, the electrons 1b cannot escape to the exterior by being absorbed into or reflected on the shield 13. Therefore, when the measurement apparatus for measuring reflected electrons from the target device 100 measures reflected electrons of the electrons incident to the exposed surface 5a (i.e. a portion where the surface thereof is Si), the signal intensity is smaller than that of the case where the shield 13 is absent. As disclosed above, while it is sufficient for the thickness of the reference mark 6 to be about a half of the range, it is desired that the shield 13 is thicker than the reference mark 6 when the shield 13 consists of the same material as the reference mark 6. This is because the electrons reflected near the surface have a high energy, the reflected electrons have energy close to that of incident electrons, and the reflected electrons with high energy pass through the shield 13 when the shield 13 has a thickness of just a half of the range.

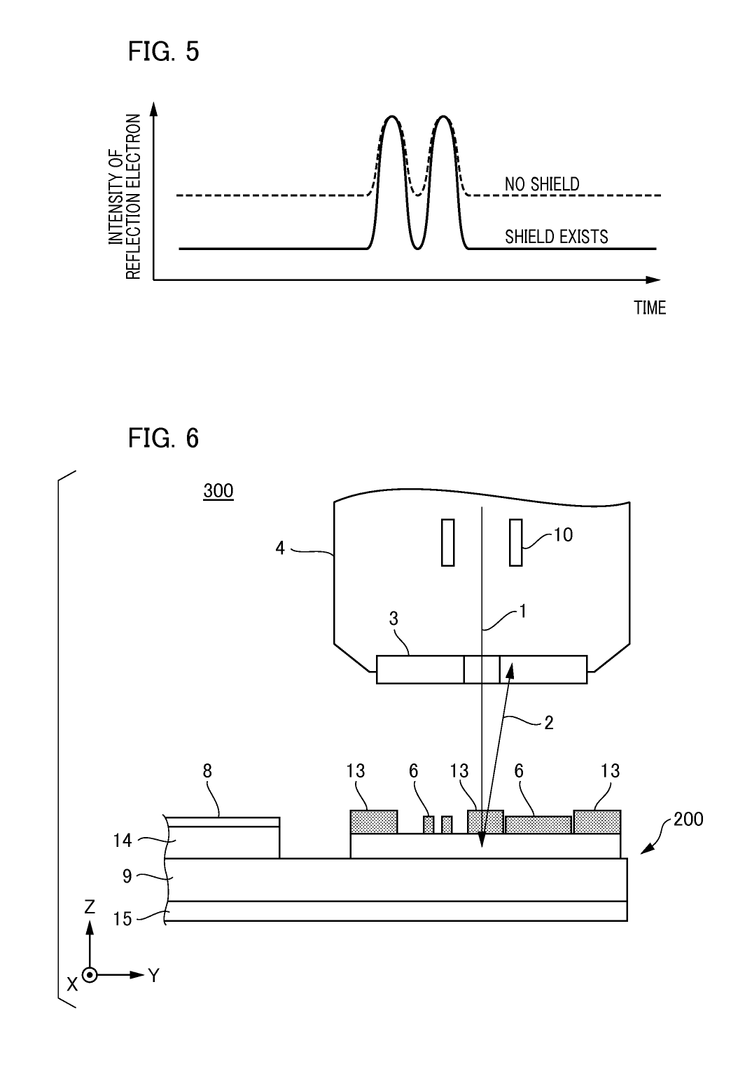

FIG. 5 is a graph illustrating the signal intensity (intensity of reflected electrons) at a time when an electron beam 1 scans the aperture region 13a. In FIG. 5, the broken line shows the case where the shield 13 is not provided on the base 5, and the solid line shows the case corresponding to the present embodiment where the shield 13 is provided on the base 5. The presence or absence of the shield 13 does not change the signal intensity (signal intensity of W) of a portion corresponding to a position of the reference mark 6. In contrast, when the shield 13 exists on the base 5, as disclosed above, the signal intensity of a position corresponding to a position of the exposed surface 5a becomes small. Consequently, the ratio of signal intensity increases, and the contrast of the signal of the reflected electrons may be improved.

As described above, according to the target device 100, the position of the reference mark 6 may be accurately measured with the external measurement apparatus by using different materials as materials constituting the base 5 and the reference mark 6 respectively, and locating the shield 13 on the base 5.

As described above, according to the present embodiment, a target device advantageous in terms of precision with which a characteristic of a charged particle beam is measured can be provided.

### Second Embodiment

Next, a description will be given of a target device according to a second embodiment of the present invention. A target device (second target device) according to the present embodiment may be applied to a drawing apparatus for drawing with a plurality of electron beams (hereinafter, referred to as “electron beam group (charged particle beam group)”) by applying the first target device 100 according to the first embodiment. FIG. 6 is a schematic cross-sectional diagram illustrating a configuration of the drawing apparatus 300 that includes the second target device 200. The drawing apparatus 300 includes an electron lens barrel (electron optical system lens barrel) 4, a wafer stage (holder) 9 that holds a wafer (substrate) 8 to be processed via a wafer chuck 14 and is movable, and a driving device 15, which are housed in a vacuum chamber (not shown). The drawing apparatus 300 performs drawing on the wafer 8 by using the electron beams in a vacuum. Note that FIG. 6 shows a state in which the electron beams irradiate to the target device 200 to cause the drawing apparatus 300 to calibrate a position. The driving device 15 moves the wafer stage 9 to position the wafer 8 with respect to the electron lens barrel 4. The electron lens barrel 4 is provided with the electron optical system that is located in the electron lens barrel 4 and includes a deflector 10 for performing deflection scanning of the electron beams 1 emitted from an electron gun (not shown). In this case, the target device 200 is located on the wafer stage 9 (on the holder), and the measuring device (detector) 3 for measuring (detecting) the reflected electrons emitted from the target device 200 is located at a position facing the wafer stage 9 of the electron lens barrel 4. The electron beams 1 accelerate to, for example, 100 keV in the electron lens barrel 4, is emitted from an opening provided at the center of the measuring device 3, and then is irradiated to the target device 200.

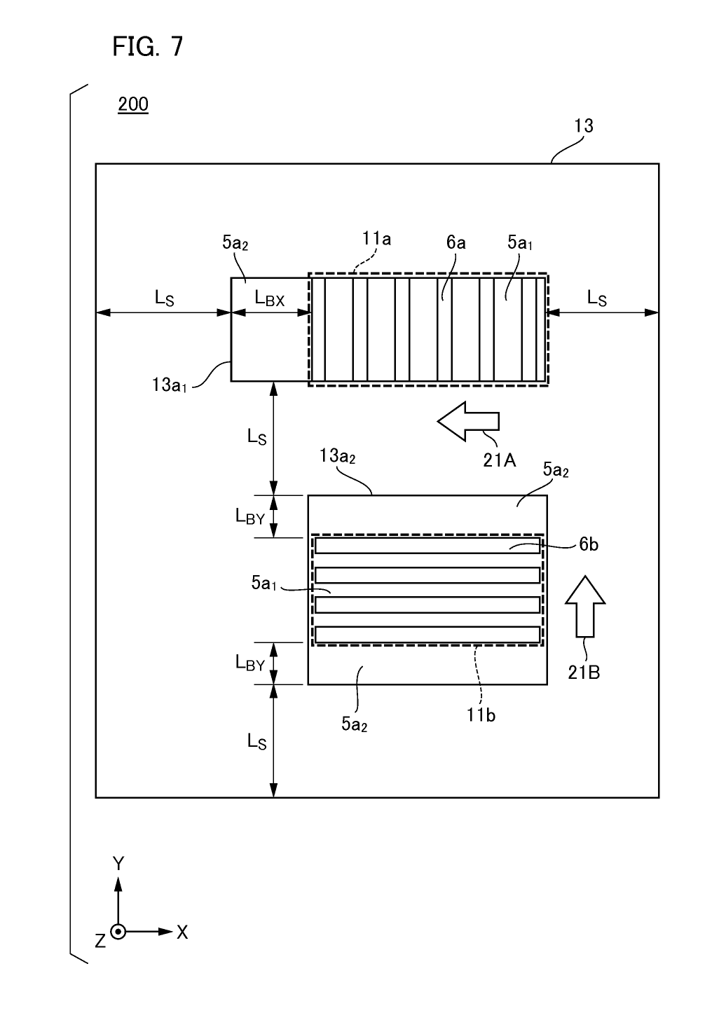

FIG. 7 is a schematic plane diagram illustrating a configuration of the target device 200. Note that with regard to each component of the target device 200, the same components as those corresponding to the target device 100 described above are designated by the same reference numerals. Similar to the target device 100, the target device 200 includes the reference mark 6 and the shield 13 around the region where the reference mark 6 is located, on the base 5 consisting of Si. The reference mark 6 may consist of W and have a thickness of 1 μm and a pattern width of 0.5 μm. In addition, the width of a space between patterns of the reference mark 6 may be 0.5 μm. Furthermore, the shield 13 may consist of W and have a thickness of 2 μm. Note that the thickness of the shield 13 may be the same as that of the reference mark 6.

In addition, FIG. 7 shows two types of reference marks, such as the reference marks 6a for measuring in the X-axis direction and the reference marks 6b for measuring in the Y-axis direction. Hereinafter, a first pattern region 11a refers to a region (circumscribed region) contacting and surrounding all the plurality of reference marks 6a, and a second pattern region 11b refers to a region contacting and surrounding all the plurality of reference marks 6b. The term “contact” implies “substantially contact”. As an example, six linear patterns extending in the Y-axis direction are arranged in parallel in the X-axis direction as the reference marks 6a including in the first pattern region 11a. As an example, four linear patterns extending in the X-axis direction are arranged in parallel in the Y-axis direction as the reference marks 6b including in the second pattern region 11b. Due to such a configuration, the shield 13 includes two aperture region s, a first aperture region 13a₁ being a region in which the plurality of reference marks 6a are located and a second aperture region 13a₂ being a region in which the plurality of reference marks 6b are located.

Furthermore, as a definition used in the following description, a “first exposed surface 5a₁” refers to a portion of the exposed surface 5a that is located between each reference mark 6 in the pattern region 11. A “second exposed surface 5a₂” refers to a portion of the exposed surface 5a that is located between the pattern region 11 and the edge of the aperture region 13a in direction parallel to each reference mark 6. In particular, “L_{B}” represents distances (widths) between the pattern region 11 and the edge of the aperture region 13a on the second exposed surface 5a₂. Among these, “L_{BX}” represents a distance (width) in the first aperture region 13a₁, and “L_{BY}” represents a distance (width) in the second aperture region 13a₂. Furthermore, “Lₛ” represents a necessary distance (width) in a direction parallel to each reference mark 6, with respect to the position of each aperture region 13a, in the shield 13.

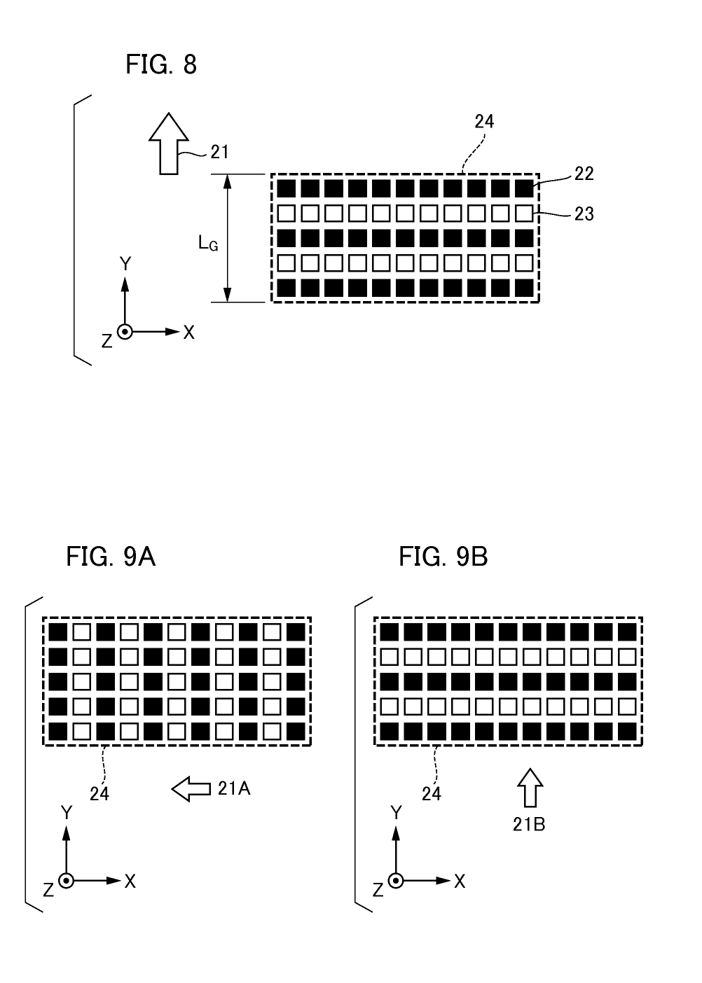

FIG. 8 is a schematic plane diagram illustrating a shape of the electron beam group 24 used in the drawing of the present embodiment. The electron beam group 24 has a shape (sequences) in which a plurality of micro scale electron beams are arranged in the matrix squares, and is defined by performing demagnification or diminution with respect to an aperture (not shown) in the electron optical system or an electron source array (not shown). Hereinafter, an individual region of the electron beams is referred to as “pixel (picture element)”. In particular, the shape of the pattern region (i.e. a rectangle circumscribing the reference marks 6) is consistent with an external form on a plane of the electron beam group 24 (i.e. a rectangle circumscribing the plurality of electron beams). Each pixel is subject to ON/OFF control separately by an operation (blanking function) of a blanking deflector (not shown) in the electron optical system. In FIG. 8, as an example, black squares represent pixels 22 in the ON (irradiation) state and white squares represent pixels 23 in the OFF (non-irradiation) state when it is assumed that the direction (measuring direction) of an arrow 21 is a scanning direction of the electron beam group 24.

The drawing apparatus 300 combines pixels 22 and pixels 23, further controls deflection scanning by the deflector 10 and movement of the wafer stage 9, relativity moves the entire electron beam group 24 with respect to the wafer 8, and then can draw any pattern on the wafer 8. In this case, the drawing apparatus 300 performs positional calibration before drawing with the target device 200 as follows.

FIGS. 9A and 9B are schematic plane diagrams illustrating irradiating states of the electron beams 1 (electron beam group 24) during positional calibrating, corresponding to the plane diagram shown in FIG. 8. Hereinafter, as an example, a description will be given of a case where the drawing apparatus 300 measures a position of the electron beams 1 in the Y-axis direction, taking the reference marks 6b for measuring in the Y-axis direction shown in FIG. 7 as an object to be measured. Firstly, the drawing apparatus 300 moves the wafer stage 9 so as to position the irradiated region of the electron beams 1 on the second pattern region 11b, and irradiates the electron beams 1 in a line-and-space shape with only pixels corresponding to the arrangement of the reference marks 6b as shown in FIG. 9B. Next, the drawing apparatus 300 controls the operation of the deflector 10 to scan with the electron beams 1 on the second aperture region 13a₂. When the electron beams 1 scan in the direction of the arrow 21B and arrive at the reference mark 6b, the electrons accelerated to 100 keV are incident to the reference mark 6b. Many electrons are scattered at a depth of about 1 μm within the reference marks 6b, arrives at the surface of the base 5, and is detected as the reflected electrons 2 by the measuring device 3. When the scan is further continued, and the electron beams 1 are incident to the base 5 (the exposed surface 5a) again, the electrons accelerated to 100 keV are reflected at a depth of dozens of μm in the base 5, and arrive at the surface of the base 5 in the extended state to dozens μm. However, according to the configuration of the present embodiment, the reflected electrons 2 are blocked by the shield 13, and cannot escape to the outside of the target device 200. Consequently, the signal intensity output from the measuring device 3 becomes small.

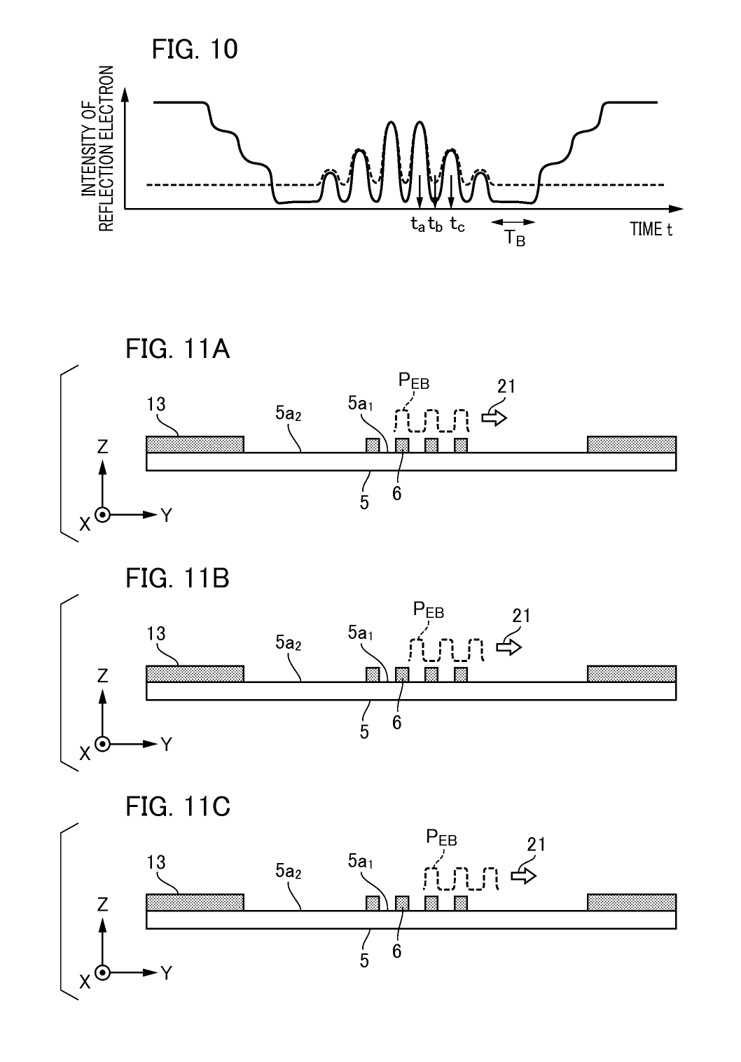

FIG. 10 is a graph illustrating a signal intensity (intensity of reflected electrons) with respect to a time, when the electron beams 1 (electron beam group 24) scans on the second aperture region 13a₂ of the target device 200 in the Y-axis direction. In FIG. 10, the broken line shows a case where the shield 13 is not provided on the base 5, the solid line shows a case corresponding to the present embodiment where the shield 13 exists on the base 5. FIGS. 11A to 11C are schematic diagrams illustrating profiles of the electron beams 1 corresponding to each time t shown in FIG. 10 by broken line. Among them, FIG. 11A corresponds to time tₐ, FIG. 11B corresponds to time t_{b}, and FIG. 11C corresponds to time t_{c}. Referring to FIG. 10 and FIGS. 11A to 11C, there is no change in the signal intensity at time tₐ and t_{c} for irradiating the reference marks 6b with the electron beams P_{EB} between the present invention and the prior art. However, at time t_{b} that the electron beams P_{EB} passes between the reference marks 6b, and at time T_{B} that the electron beam P_{EB} passes through the second pattern region 11b and the entire electron beams P_{EB} irradiate the exposed surface 5a between the second pattern region and the shield 13, the signal intensity of the present embodiment is smaller than that of the prior art.

Note that the relative position between the wafer stage 9 and the target device 200 located on the wafer stage 9 is specified in advance by measurement with an optical device or the like. Thus, if the position of the target device 200 can be measured with the electron beams 1, the relationship of relative position between the electron beams 1 and the wafer stage 9 in the Y-axis direction can be finally determined.

In contrast, when the position of the electron beams 1 is measured in the X-axis direction, the drawing apparatus 300 takes the reference marks 6a for measuring in the X-axis direction shown in FIG. 7 as an object to be irradiated. Firstly, the drawing apparatus 300 moves the wafer stage 9 so as to position the irradiated region of the electron beams 1 on the first pattern region 11a, and irradiates the electron beams 1 in a line-and-space shape with only pixels corresponding to the arrangement of the reference marks 6a as shown in FIG. 9A. The drawing apparatus 300 controls the operation of the deflector 10 to scan on the first aperture region 13a₁ with the electron beams 1. Finally, while the electron beams 1 irradiated as shown in FIG. 9A scans in a direction of the arrow 21A, the reflected electrons 2 are measured as disclosed above, and thereby the relationship of the relative position between the electron beams 1 and the wafer stage 9 in the X-axis direction can be determined.

Next, a description will be given of a shape condition of the shield 13 in the target device 200. Here, basis of the shape conditions is that the reflected electrons 2 caused by the electron beams 1 incident to the base 5 from the first exposed surface 5a₁ in the pattern region 11 do not escape to the outside by being shielded by the shield 13. Therefore, an effective area of the shield 13 is preferably set such that the distance L_{B} between the pattern region 11 and the edge of the aperture region 13a on the second exposed surface 5a₂ becomes as small as possible. Hereinafter, the following description is based on the direction parallel to the scanning direction of the electron beams 1 and the direction perpendicular to the scanning direction as specific shape condition.

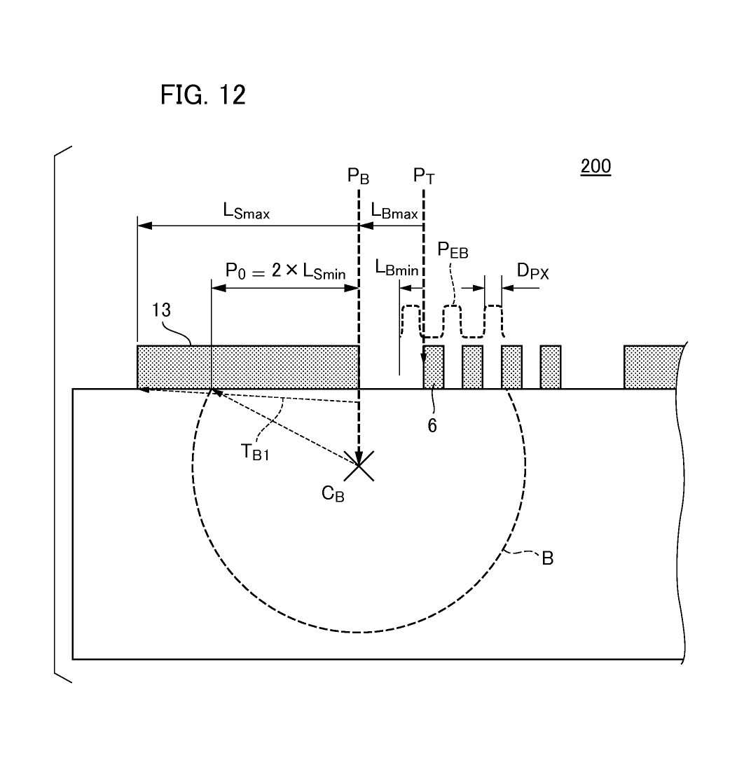

Firstly, a description will be given of a shape condition in the direction parallel to the scanning direction of the electron beams 1. FIG. 12 is a schematic cross-sectional diagram illustrating a partial configuration (the vicinity of the second aperture region 13a₂) of the target device 200 in order to explain the shape condition of the shield 13. It is assumed that the maximum distance L_{Smax} that the electron beam P_{B} incident from the edge of second aperture region 13a₂, that is, the outermost position of the exposed surface 5a can escape from the surface of the base 5, is equal to the range R_{eB} of electrons within the base 5 when the electrons scattered near to the surface of the base 5 pass a path T_{B1}. Next, an area is considered where the electrons may arrive from the point C_{B}, which is a center when the electrons incident into the base 5 scatter, as an area where the suppression effect for separating the reflected electrons can be provided. The circle “B” with a 3R_{eB}/4 radius from the point C_{B} is an arriving limit of the electrons scattering at the point C with a R_{eB}/4 depth, and almost all of reflected electrons to escape from the base 5 are within the radius R₀. Furthermore, in the case where it is considered that the suppression separation effect can be provided in a distance of about a half of R₀, the shortest distance L_{Smin} in the shield 13 is represented by Equation 4.

[Equation 4]

L_{S min}=R₀/2=1/2\sqrt{(3R_{eB}/4)²−(R_{eB}/4)²}=\sqrt{2}R_{eB}/4 (4)

Moreover, the range of distance L_{S} in the shield 13 in this case is represented by Equation 5.

$$\begin{matrix}[ Equation 5 ] & \\ \frac{\sqrt{2} {R}_{eB}}{4} < {L}_{s} < {R}_{eB} & ( 5 )\end{matrix}$$

In addition, the range of distance L_{B} (L_{BY}) in the second exposed surface 5a₂ is the condition in which a pixel line at the edge of profile P_{EB} of the electron beams that are the same as that shown in FIGS. 11A to 11C passes through the second pattern region 11a₂ as shown in FIG. 12, and does not cover the shield 13. In other words, the shortest distance L_{Bmin} has to set to be larger than the width D_{PX} of a pixel. In contrast, considering the longest distance L_{Bmax} in the second exposed surface 5a₂, even if the distance L_{B} is longer than the width L_{G} of pixel group in the scanning direction (see FIG. 8), a time interval T_{B} shown in FIG. 10 becomes longer, but the position information does not increase. In addition, if the distance L_{B} becomes longer, the suppression separation effect is reduced. In other words, the longest distance L_{Bmax} is assumed to be the distance (width) L_{G} of pixel group in the scanning direction. In order to sufficiently measure the reflected electrons from the reference mark 6, the distance L_{B} has to become longer than the range R_{eT}. Thus, the longest distance L_{BmaX} is the maximum value “max” (L_{G}, R_{eT}) that shows the larger one of the distance L_{G} and the range R_{eT}. Finally, in this case, the distance L_{B} in the second exposed surface 5a₂ is represented by Equation 6.

[Equation 6]

D_{PX}<L_{B}<max(L_{G}, R_{eT}, ) (6)

Next, a description will be given of a shape condition in a direction perpendicular to the scanning direction of the electron beams 1. In this case, the area of the distance L_{S} in the shield 13 is represented by Equation 5) that is the condition with regard to the direction parallel to the scanning direction of the electron beams 1 as disclosed above. In contrast, the distance L_{B} in the second exposed surface 5a₂ in this case may not be specifically defined, but preferably be represented by Equation 7

[Equation 7]

0<L_{B}<R_{eT} (7)

Here, specific numerical values are applied to the above shape conditions. Firstly, as explained above, if the range is R_{eB}=54 μm, the distance L_{S} is as follows by using Equation 5.

19 μm<L_{S}<54 μm

In addition, if a size (distance L_{G}) of the electron beam group 24 is 20 μm in the X-axis direction and 2 μm in the Y-axis direction, the width D_{PX} of a pixel is 0.5 μm, and the range is R_{eT}=3.9 μm, the distance L_{B} in the second exposed surface 5a₂ is as follows by using Equation 6.

0.5 μm<L_{BX}<20 μm

0.5 μm<L_{BY}<3.9 μm

As disclosed above, the target devices 100 and 200 use the base 5, the reference mark 6, and the shield 13, for which the materials constituting them and the shapes thereof are selected (defined). The external measurement apparatus (measuring device 3) for measuring the reference mark 6 may obtain a higher ratio of signal intensity (or the contrast in the signal of reflected electrons) than the prior art by using such target devices 100 and 200. In other words, the target devices 100 and 200 can cause the external measurement apparatus to accurately measure the position of the reference mark a 6. In addition, the target devices 100 and 200 are advantageous for using a single electron beam to be irradiated and a plurality of electron beams (electron beam group). In particular, when the electron beam group consisting of a plurality of pixels is irradiated, as disclosed above, a small amount of electron beams is often irradiated from one pixel even if this pixel is in the non-irradiation state. However, according to the target device 200, the high ratio of signal intensity can be obtained in this case. Thus, the present embodiment has the same effects as the first embodiment.

Note that the material of the base 5 is Si in the above embodiments, but the present invention is not limited thereto. The material of the base 5 is preferably a material having a larger range Rₑ of electrons than that of the material of the reference mark 6, and is desirably a material with the atomic number of 30 or less of the primary element, for example, such as C or Si, or a metal of Al, Cu, Ni or Be as well as Si. In addition, while the material of the reference mark 6 is W in the present embodiment, the present invention is not limited thereto. The material of the reference mark 6 is preferably a material having a smaller range Rₑ of electrons than that of the material of the base 5, and is desirably a material with the atomic number of 73 or more of the primary element, for example, such as a heavy metal of Ta, Au or Pt as well as W.

Moreover, in the second embodiment, the second exposed surface 5a₂ is arranged at both sides of the second pattern region 11b in the scanning direction on the second aperture region 13a₂. In contrast, the second exposed surface 5a₂ is arranged at only one side of the first pattern region 11a in the scanning direction on the first aperture region 13a₁. Therefore, the second exposed surface 5a₂ is not necessarily arranged at both sides of the pattern region 11. This is because the suppression effect to escape the reflected electrons in the present embodiment can be obtained when the shortest distance L_{Bmin} is larger than the width D_{PX} of a pixel, that is, when one peak of the profile P_{EB} of the electron beams can be obtained.

Furthermore, while the shield 13 has the aperture region 13 as a region for arranging the pattern region 11 in the above embodiments, the region is not necessarily an opening. As disclosed above, in order to obtain the suppression separation effect of the present embodiment, the shape of the shield 13 is considered mainly in the scanning direction. Thus, there is a case where the shield 13 is arranged at both sides in the scanning direction, but is not arranged in a direction orthogonal to the scanning direction with respect to the arrangement of the pattern region 11, that is, the shield 13 may not be integrally formed, and there may be a plurality of components of the shield 13 present on the base 5.

Moreover, in the second embodiment, although the electron beam group 24 is arranged in the matrix squares, it may be arranged in latticed shape in accordance with predetermined rule and may have a configuration that the specific electron beams can be driven from the outside, such as in checkers, honeycomb shape or one row. The electrons of the electron beam group 24 are not necessarily controlled separately, and the electrons may be controlled together.

### Third Embodiment

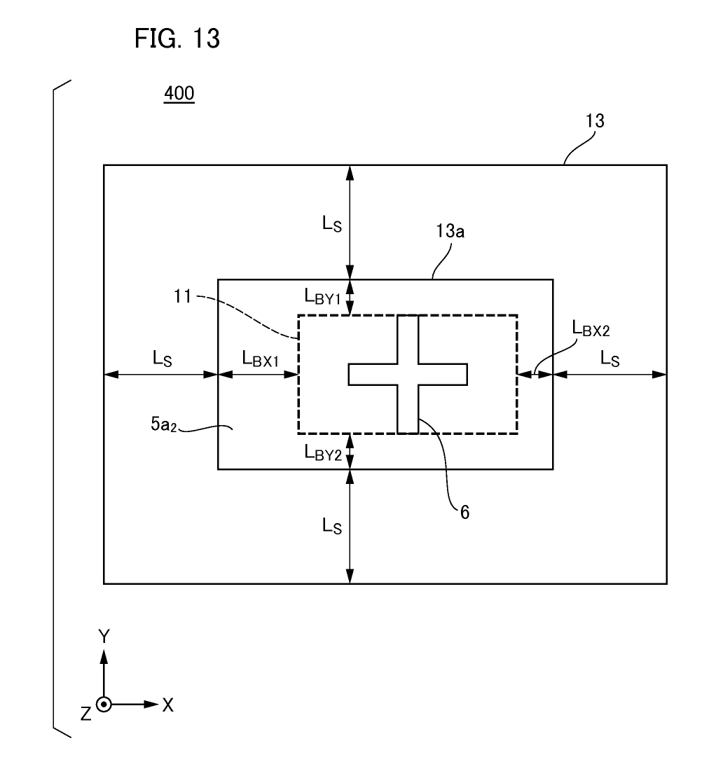

Next, a description will be given of a target device according to a third embodiment of the present invention. A feature of the target device according to the present embodiment lies in the fact that the shapes of the reference mark 6 and the shield 13 are changed from the shapes in the second target device 200 according to the second embodiment. FIG. 13 is a schematic plane diagram illustrating a configuration of a target device 400 according to the present embodiment. Note that with regard to each component of the target device 400, the same components as those corresponding to the target device 200 are designated by the same reference numerals. Similar to the target device 200, the target device 400 may be applied to the drawing apparatus for drawing with the electron beam group. In addition, in the target device 400, the materials constituting of the base 5, the reference mark 6, and the shield 13 may each be the same as those in the target device 200. The target device 200 according to the second embodiment includes two reference marks of the reference marks 6a for measuring in the X-axis direction and the reference marks 6b for measuring in the Y-axis direction, and the shield 13 having two aperture regions 13a₁ and 13a₂ corresponding to the reference marks 6a and 6b on the base 5 as shown in FIG. 7. In contrast, the target device 400 according to the present embodiment includes a reference mark 6 that is a cross shaped pattern having a plane shape, the long side of which is parallel to the scanning direction, and the shield 13 having one aperture region 13a corresponding to the shape of the reference mark 6, on the base 5 as shown in FIG. 13.

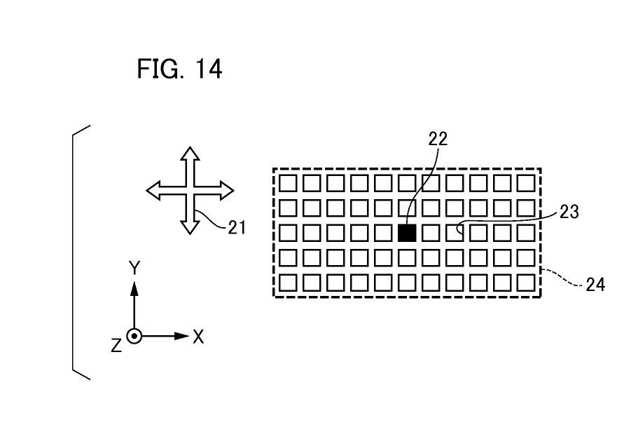

FIG. 14 is a schematic plane diagram illustrating an irradiating state of the electron beams 1 (electron beam group 24) during positional calibration in the present embodiment, corresponding to the plane diagram shown in FIG. 8. When the positional calibration is performed with the reference mark 6 of the present embodiment, considering that the electron beam group 24 has the same external shape as that in the second embodiment, the drawing apparatus 300 causes only one pixel 22 at the center region of the electron beam group 24 to be irradiated. The drawing apparatus 300 controls the operation of the deflector 10 and determines the relationship of the relative position between the electron beams 1 and the wafer stage 9 in the X-axis and the Y-axis directions by scanning the electron beams 1 on the aperture region 13a in a cross shaped direction as shown by the arrow 21 and measuring the reflected electrons 2.

The size (shape) of the pattern region 11 in the present embodiment may be equivalent to the size of the electron beam group 24. The reference mark 6 included in the inside of the pattern region 11 has a size sufficient to contact both ends of the cross shape in one direction with the centers of each long side of the pattern region 11 respectively. In the present embodiment, “L_{BX1}” and “L_{BX2}” refer to two distances (widths) in the X-axis direction between the edge of the aperture region 13a and the pattern region 11 on the second exposed surface 5a₂, and “L_{BY1}” and “L_{BY2}” refer to two distances (widths) in the Y-axis direction. Moreover, “L_{S}” refers to a distance (width) required by the aperture region 13 in the X-axis and Y-axis directions in the shield 13.

As explained in the second embodiment, each pixel 23 of pixels in the electron beam group 24, which are controlled so as not to irradiate, may emit the small electron beam. Thus, in the case disclosed in the present embodiment, as described above, while it is considered that the size of the pattern region 11 is equivalent to the size of the electron beam group 24, specific values of the distances L_{B} and L_{S} may be determined by using Equation 5 and Equation 6 shown in the second embodiment. If the distance LB varies by the scanning direction of the electron beams 1, it is desirable that the different distances L_{B} are determined separately.

As disclosed above, the present embodiment has the same effect as that of the second embodiment by using the same material constituting of each component for that of the second embodiment and selecting (defining) the shape of the shield 13 by using the above conditions, even if the reference mark 6 has a different shape from the second embodiment.

### Fourth Embodiment

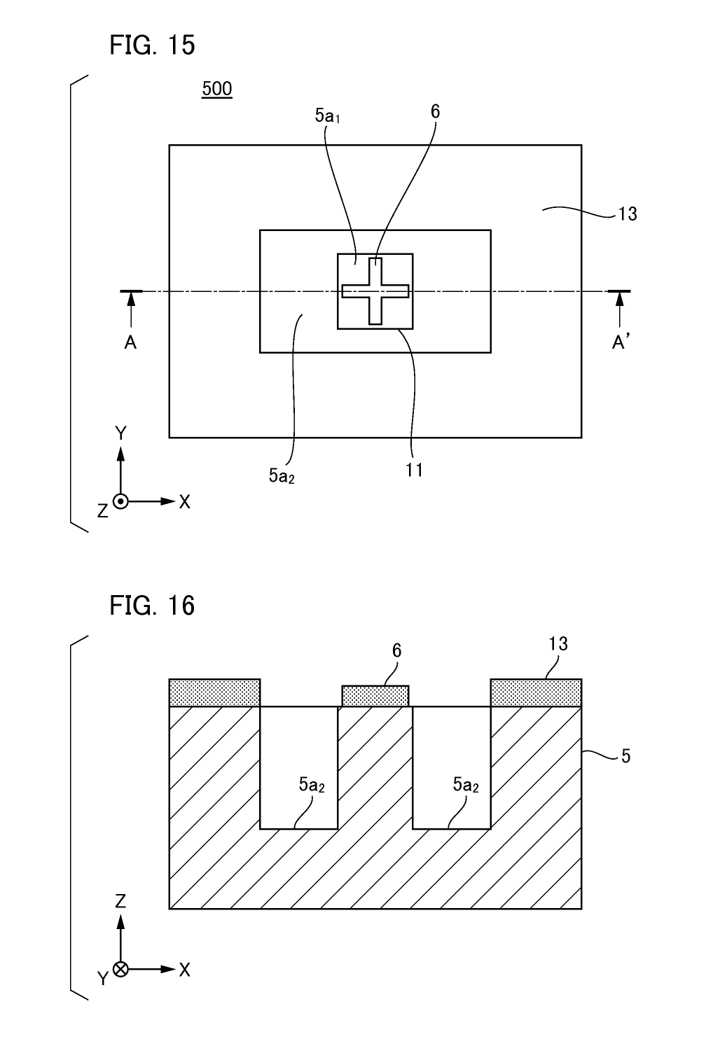

Next, a description will be given of a target device according to a fourth embodiment of the present invention. A feature of the target device according to the present embodiment lies in the fact that a concave portion is further arranged in the exposed surface 5a while the reference mark 6 and the shield 13, which are formed by the same material and in the same shape as the third embodiment, are used. FIG. 15 is a schematic plane diagram illustrating a configuration of a target device 500 according to the present embodiment. Note that with regard to each component of the target device 500, the same components as those corresponding to the target device 200 are designated by the same reference numerals. FIG. 16 is a schematic diagram illustrating an A-A′ cross section of FIG. 15. Note that when the positional calibration is performed in the present embodiment, as the third embodiment, only one pixel 22 that is at the center region of the electron beam group 24 is irradiated, as shown in FIG. 14. Firstly, the pattern region 11 in the present embodiment has a square shape that substantially contacts the four ends of cross shaped reference mark 6, and the first exposed surface 5a₁ refers to a region that, excluding the area where the reference mark 6, is located in the pattern region 11. In contrast, the second exposed surface 5a₂ which is a region that, excluding the pattern region 11 in the aperture region 13a, refers to the bottom of the concave portion formed by engraving a port of the base 5 using etching process or the like as shown in FIG. 15.

According to this configuration, if the surface of the reference mark 6 is set to the reference, the scattering point of the electrons incident from the second exposed surface 5a₂ in the base 5 is deeper than the point C_{B} in the base 5 shown in FIG. 12 of the second embodiment. Therefore, in comparison to configurations of the above embodiments, the extent of the reflected electrons on the surface of the reference mark 6 increases. In addition, the number of reflected electrons separating to the outside from the target device 500 is reduced since the number of reflected electrons blocked by the shield 13 increases. Accordingly, the present embodiment may further improve the ratio of signal intensity (or the contrast of the reflected electrons). While the target device using the electron beam group is explained in the present embodiment, the present embodiment may be applied to the target device using a single electron beam, as the first embodiment.

### (Article Manufacturing Method)

A method of manufacturing an article according to an embodiment of the present invention is suitable for manufacturing an article such as a microdevice (for example, a semiconductor device) or an element having a microstructure. This manufacturing method can include a step of forming a pattern (for example, a latent image pattern) on an object (for example, a substrate having a photosensitive agent on the surface) by using the above-described lithography apparatus, and a step of processing the object on which the pattern is formed (for example, a developing step). Further, this manufacturing method includes other well-known steps (for example, oxidization, deposition, vapor deposition, doping, planarization, etching, resist removal, dicing, bonding, packaging and the like). The method of manufacturing an article according to the embodiment is superior to a conventional method in at least one of the performance, quality, productivity, and production cost of the article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-095021 filed May 2, 2014, which is hereby incorporated by reference herein in its entirety.

1. A target device for scattering a charged particle incident thereon, the device comprising:
a base;
a reference mark provided on the base and having a range of the charged particle therein smaller than a range of the charged particle in the base; and
a shield provided on the base apart from the reference mark and having a range of the charged particle therein smaller than the range of the charged particle in the base.

2. The device according to claim 1, wherein the shield is provided so as to cover a portion of an area in a surface of the base from which the charged particle incident on the base escapes by backscatter thereof.

3. The device according to claim 1, wherein a surface of the base in a region between the reference mark and the shield is lower than that in a region where the reference mark and the shield are located.

4. The device according to claim 1, wherein a material of the base includes a metal.

5. The device according to claim 1, wherein a material of the base includes an element of one of C, Si, Al, Cu, Ni and Be.

6. The device according to claim 1, wherein a material of the reference mark includes a metal.

7. The device according to claim 1, wherein a material of the reference mark includes an element of one of Ta, W, Au and Pt.

8. The device according to claim 1, wherein a material of the shield includes a metal.

9. The device according to claim 1, wherein a material of the shied includes an element of one of Ta, W, Au and Pt.

10. The device according to claim 1, wherein the shield is thicker than the reference mark.

11. A lithography apparatus for performing patterning on a substrate with a charged particle beam, the apparatus comprising:
a target device, for scattering a charged particle incident thereon, the device comprising:
a base;
a reference mark provided on the base and having a range of the charged particle therein smaller than a range of the charged particle in the base; and
a shield provided on the base apart from the reference mark and having a range of the charged particle therein smaller than the range of the charged particle in the base; and
detector configured to detect a charged particle scattered by the target device.

12. The apparatus according to claim 11, further comprising
a holder configured to hold the substrate and to be movable
wherein the holder is provided with the target device.

13. The apparatus according to claim 11, further comprising:
an optical system configured to irradiate the substrate with a plurality of charged particle beams and having a blanking function,
wherein the optical system is configured to blank a portion of the plurality of charged particle beams by the blanking function based on a region of the reference mark.

14. The apparatus according to claim 13, wherein a rectangle circumscribing the reference mark is consistent with a rectangle circumscribing the charged particle beams on the target device.

15. The apparatus according to claim 12, further comprising:
a measuring device configured to measure a characteristic of the charged particle beam in a measurement direction on the target device based on an output of the detector,
wherein a condition that
D_{PX}<L_{B}<max(L_{G}, R_{eT})
is satisfied, where a width of a pixel on the target device, corresponding to each of the plurality of charged particle beams, is represented by D_{PX}, a width of pixels on the target device in the measurement direction, corresponding to the plurality of charged particle beams, is represented by L_{G}, a range of a charged particle, of the plurality charged particle beams, in the reference mark is represented by R_{eT}, and a width of the base between the reference mark and the shield in the measurement direction is represented by L_{B}.

16. The apparatus according to claim 12, further comprising:
a measuring device configured to measure a characteristic of the charged particle beam in a measurement direction on the target device based on an output of the detector,
wherein a condition that
$$\frac{\sqrt{2} {R}_{eB}}{4} < {L}_{s} < {R}_{eB}$$
is satisfied, where a range of a charged particle, of the plurality of charged particle beams, in the base is represented by R_{eB}, and a width of the shield in the measurement direction is represented by L_{S}.

17. A method of manufacturing an article, the method comprising steps of:
performing patterning on a substrate using a lithography apparatus; and
processing the substrate, on which the patterning has been performed, to manufacture the article,
wherein the lithography apparatus performs patterning on the substrate with a charged particle beam, and includes:
a target device for scattering a charged particle incident thereon, the device including:
a base;
a reference mark provided on the base and having a range of the charged particle therein smaller than a range of the charged particle in the base; and
a shield provided on the base apart from the reference mark and having a range of the charged particle therein smaller than the range of the charged particle in the base.
